(19) United States
(12) Patent Application Publication
(10) Pub. No.: US 2026/0290482 A1
(43) Pub. Date: Sep. 24, 2026

(54) MEMORY DEVICE

(71) Applicant: Kioxia Corporation, Tokyo (JP)

(72) Inventor: Masayoshi IWAYAMA, Nagoya Aichi (JP)

(73) Assignee: Kioxia Corporation, Tokyo (JP)

(21) Appl. No.: 19/324,492

(22) Filed: Sep. 10, 2025

(30) Foreign Application Priority Data
Mar. 21, 2025 (JP) 2025-047104

(51) Int. Cl. G11C 29/12; G11C 29/02

(52) U.S. Cl. CPC G11C 29/1201; G11C 29/028; G11C 29/12005

(57) ABSTRACT

According to one embodiment, a memory device includes memory cell blocks and sense amplifier circuits, and a control circuit. The amplifier circuits includes a first circuit portion through which a first current flows obtained by reading target data, a second circuit portion through which a second current flows obtained by reading reference data, a third circuit portion connected in parallel to the second circuit portion, through which a third current flows when the second current flows, and an output portion outputting a detection signal corresponding to the target data based on a relationship between the first current and a total current of the second and third currents. The control circuit adjusts the third current with respect to each sense amplifier circuit.

### CROSS-REFERENCE TO RELATED APPLICATIONS

This application is based upon and claims the benefit of priority from Japanese Patent Application No. 2025-047104, filed Mar. 21, 2025, the entire contents of which are incorporated herein by reference.

### FIELD

Embodiments described herein relate generally to a memory device.

### BACKGROUND

Memory devices have been proposed in which a plurality of memory cells, each including a magnetoresistance effect element (variable resistance element) and a selector (switching element) are integrated on a semiconductor substrate.

### BRIEF DESCRIPTION OF THE DRAWINGS

FIG. 1 is a block diagram showing a basic configuration of a memory device according to an embodiment.

FIG. 2 is a perspective view schematically showing a configuration of a memory cell block of the memory device according to the embodiment.

FIG. 3 is a cross-sectional view schematically showing a basic configuration of a magnetoresistance effect element of the memory device according to the embodiment.

FIG. 4 is a cross-sectional view schematically showing a basic configuration of a selector of the memory device according to the embodiment.

FIG. 5 is a flowchart showing an operation of self-reference read in the memory device according to the embodiment.

FIG. 6 is a timing diagram showing the operation of the self-reference read in the memory device according to the embodiment.

FIG. 7 is an electrical circuit diagram showing a configuration of a sense amplifier circuit of the memory device according to the embodiment.

FIG. 8 is a diagram schematically showing the relationship between various currents flowing through transistors included in the sense amplifier circuit of the memory device according to the embodiment.

FIG. 9 is a diagram showing a method for determining the offset voltage of the memory device according to the embodiment.

FIG. 10 is a flowchart showing the operation of the memory device according to the embodiment.

FIG. 11 is a diagram showing a trimming process in the memory device according to the embodiment.

### DETAILED DESCRIPTION

In general, according to one embodiment, a memory device includes a memory circuit including a plurality of memory cell blocks each including a plurality of memory cells, and a plurality of sense amplifier circuits provided for the plurality of memory cell blocks, respectively; and a control circuit controlling the memory circuit, wherein each of the plurality of memory cells includes a variable resistance element and a switching element connected in series with the variable resistance element, and stores data corresponding to one of a low-resistance state and a high-resistance state of the variable resistance element, each of the plurality of sense amplifier circuits includes: a first circuit portion through which a first current flows, the first current depending on a first value obtained by a first read operation that reads target data stored in a selected memory cell of the plurality of memory cells; a second circuit portion through which a second current flows, the second current depending on a second value obtained by a second read operation that reads reference data written to the selected memory cell during a write operation performed after the first read operation; a third circuit portion connected in parallel to the second circuit portion, through which a third current flows when the second current flows through the second circuit portion; and an output portion which outputs a detection signal corresponding to the target data based on a relationship between a magnitude of the first current and a magnitude of a total current of the second current and the third current, and the control circuit includes an adjustment circuit which adjusts the third current flowing through the third circuit portion with respect to each of the plurality of sense amplifier circuits.

The embodiments will now be described with reference to the drawings.

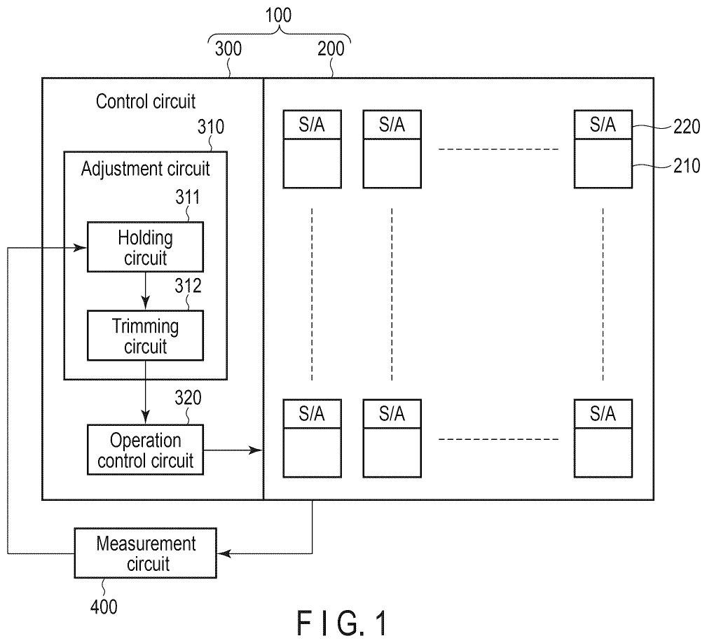

FIG. 1 is a block diagram schematically showing a basic configuration of the memory device according to an embodiment.

A memory device 100 shown in FIG. 1 includes a memory circuit 200 and a control circuit 300 that controls the memory circuit 200, and the memory circuit 200 and the control circuit 300 are provided in the same semiconductor integrated circuit chip.

The memory circuit 200 includes a plurality of memory cell blocks 210 and a plurality of sense amplifier circuits 220 provided for the memory cell blocks 210, respectively. That is, one sense amplifier circuit 220 is provided for each memory cell block 210. Each of the memory cell blocks 210 includes a plurality of memory cells. Note that FIG. 1 is merely a block diagram and does not specifically illustrate the actual arrangement of the memory cell blocks 210, sense amplifier circuits 220, and the like.

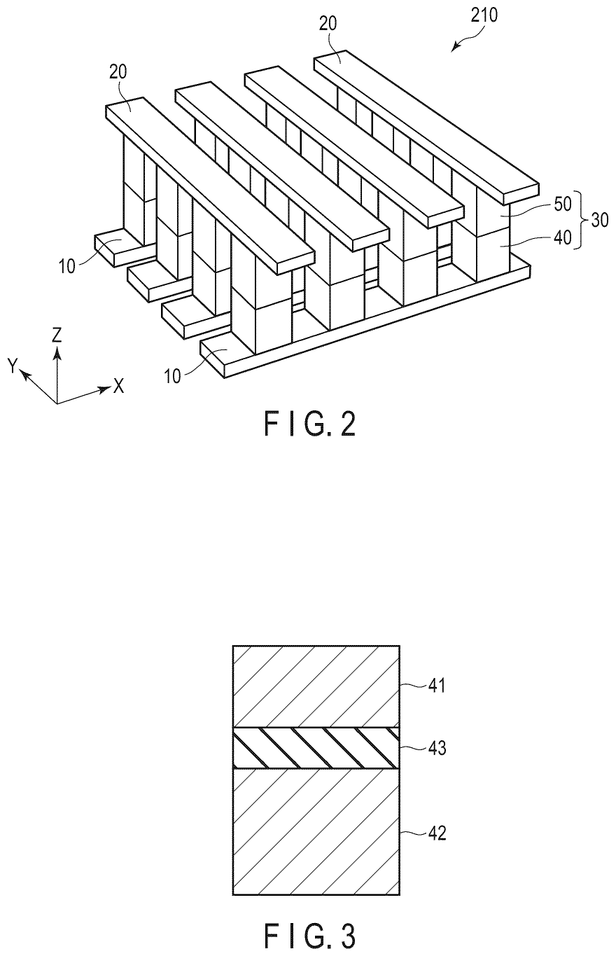

FIG. 2 is a perspective view schematically showing a configuration of a memory cell block 210. Note that an X direction, a Y direction, and a Z direction shown in the figure intersect each other. Specifically, the X direction, Y direction, and Z direction are orthogonal with respect to each other.

The memory cell block 210 includes a plurality of lower wiring lines 10 each extending along the X direction, a plurality of upper wiring lines 20 each extending along the Y direction, and a plurality of memory cells 30 connected between the lower wiring lines 10 and the upper wiring lines 20. One set of the lower wiring lines 10 and the upper wiring lines 20 corresponds to word lines, while the other set of the lower wiring lines 10 and the upper wiring lines 20 corresponds to bit lines.

Each of the memory cells 30 includes a magnetoresistance effect element (non-volatile variable resistance element) 40 that exhibits one of a low-resistance state or a high-resistance state, and a selector (switching element) 50 connected in series to the magnetoresistance effect element 40, and stores different information (data) corresponding to the resistance state of the magnetoresistance effect element 40.

The magnetoresistance effect element 40 and the selector 50 are stacked along the Z direction. That is, the magnetoresistance effect element 40 and the selector 50 are stacked in a direction perpendicular to the plane (XY plane) on which the memory cells 30 are arranged.

FIG. 3 is a cross-sectional view schematically illustrating the basic configuration of the magnetoresistance effect element 40.

The magnetoresistance effect element 40 is a magnetic tunnel junction (MTJ) element including a storage layer 41, a reference layer 42, and a tunnel barrier layer 43, which has a configuration in which the storage layer 41, the reference layer 42, and the tunnel barrier layer 43 are stacked along the Z direction shown in FIG. 1.

The storage layer 41 is a ferromagnetic layer having a variable magnetization direction. The reference layer 42 is a ferromagnetic layer having a fixed magnetization direction. The tunnel barrier layer 43 is an insulating layer and is a nonmagnetic layer provided between the storage layer 41 and the reference layer 42. Note that the term “variable magnetization direction” means that the magnetization direction changes for a predetermined write current. Further, the term “fixed magnetization direction” means that the magnetization direction does not change for a predetermined write current.

When the magnetization direction of the storage layer 41 is parallel to the magnetization direction of the reference layer 42, the magnetoresistance effect element 40 is in the low-resistance state. When the magnetization direction of the storage layer 41 is antiparallel to the magnetization direction of the reference layer 42, the magnetoresistance effect element 40 is in the high-resistance state. With this configuration, the memory cell 30 can store data corresponding to one the low-resistance state and the high-resistance state of the magnetoresistance effect element 40. In other words, the memory cell 30 can store binary data corresponding to the resistance state set in the magnetoresistance effect element 40.

Specifically, by applying a write current to the magnetoresistance effect element 40, one of the low-resistance state and high-resistance state can be set in the magnetoresistance effect element 40, and by applying a read current to the magnetoresistance effect element 40, the resistance state set in the magnetoresistance effect element 40 can be read.

Note that FIG. 3 illustrates the magnetoresistance effect element 40 of a top-free type in which the storage layer 41 is located on the upper layer side of the reference layer 42, but a bottom-free type in which the storage layer 41 is located on the lower layer side of the reference layer 42 may as well be used.

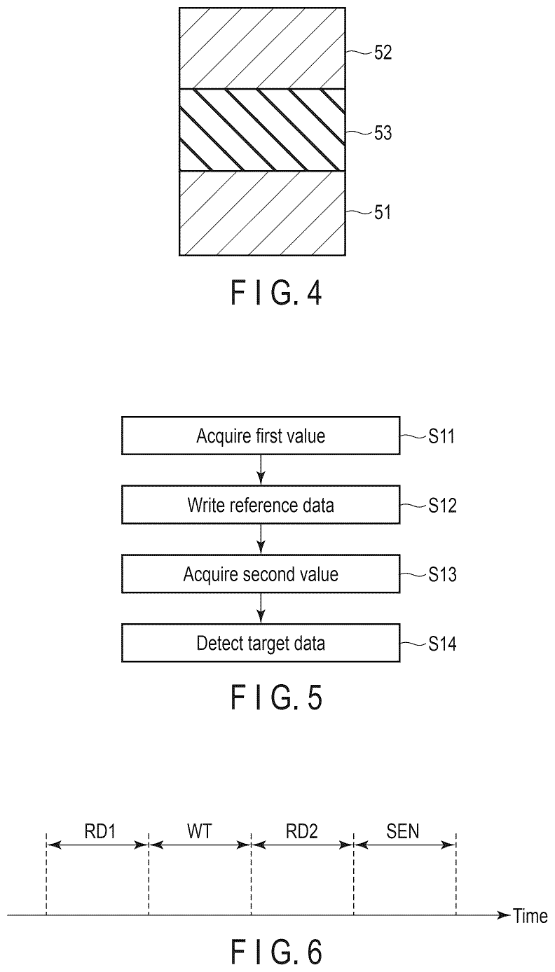

FIG. 4 is a cross-sectional view schematically showing the basic configuration of the selector 50.

The selector 50 is a two-terminal switching element including a bottom electrode 51, a top electrode 52, and a selector material layer 53 disposed between the bottom electrode 51 and the top electrode 52, and having a configuration in which the bottom electrode 51, the top electrode 52, and the selector material layer 53 are stacked along the Z direction shown in FIG. 1.

The selector material layer 53 is basically an insulating layer. Note here that when the voltage applied between the two terminals (between the bottom electrode 51 and the top electrode 52) reaches or exceeds a threshold voltage, the resistance drops significantly, thereby setting to a conductive state. Therefore, the selector 50 has the characteristic of changing from an off state to an on state when the voltage applied between the bottom electrode 51 and the top electrode 52 reaches or exceeds the threshold voltage.

With the configuration described above, when a voltage is applied between the lower wiring line 10 and the upper wiring line 20, and the voltage applied between the bottom electrode 51 and the top electrode 52 reaches or exceeds the threshold voltage, the selector 50 enters the on state. As a result, current flows through the magnetoresistance effect element 40 connected in series with the selector 50, enabling writing (setting to the low-resistance state or high-resistance state) or reading (detection of the low-resistance state or high-resistance state) of the magnetoresistance effect element 40.

Note that in FIG. 2, the magnetoresistance effect element 40 is located on the lower layer side of the selector 50, but the magnetoresistance effect element 40 may as well be located on the upper layer side of the selector 50.

Returning to the explanation of FIG. 1, each of the sense amplifier circuits 220 has the function of reading out (detecting) the target data (data to be read) stored in the selected memory cell among a plurality of memory cells included in the corresponding memory cell block 210. In other words, the sense amplifier circuit 220 has the function of reading out (detecting) the target data corresponding to the resistance state (the low-resistance state or high-resistance state) set in the magnetoresistance effect element 40 included in the selected memory cell 30.

First, the self-reference read performed using the sense amplifier circuit 220 will be described.

As already described above, the magnetoresistance effect element has two resistance states: the low resistance state and the high resistance state. The resistance state of the magnetoresistance effect element is determined by comparing the value (voltage value or current value) obtained according to the resistance state set in the magnetoresistance effect element with a reference value.

FIG. 5 is a flowchart showing the operation of the self-reference read. FIG. 6 is a timing diagram showing the operation of the self-reference read.

First, in the first read operation performed during a period RD1, a first value based on the target data stored in the selected memory cell 30 is acquired (S11). That is, the first value based on the target resistance state (the resistance state corresponding to the read target data) set in the magnetoresistance effect element 40 included in the selected memory cell 30 is acquired. Specifically, a read current is allowed to flow to the magnetoresistance effect element 40, and the first voltage is acquired as the first value.

Next, in the write operation performed during a period WT following the period RD1, reference data is written to the selected memory cell 30 (S12). That is, one of the low-resistance state and high-resistance state is set as the reference resistance state to the magnetoresistance effect element 40 included in the selected memory cell 30. Specifically, a write current is allowed to flow to the magnetoresistance effect element 40, and the reference resistance state is set to the magnetoresistance effect element 40.

Next, in the second read operation performed during a period RD2 following the period WT, a second value based on the reference data stored in the selected memory cell 30 is acquired (S13). That is, a second value based on the reference resistance state set to the magnetoresistance effect element 40 included in the selected memory cell 30 is acquired. Specifically, a read current is allowed to flow to the magnetoresistance effect element 40, and the second voltage is obtained as the second value.

Then, in the detection operation (judgment operation) performed during the period SEN following the period RD2, the target data stored in the memory cell 30 prior to the first read operation is detected based on the first and second values obtained in the first and second read operations, respectively (S14). The detection operation is performed in the sense amplifier circuit 220 as follows.

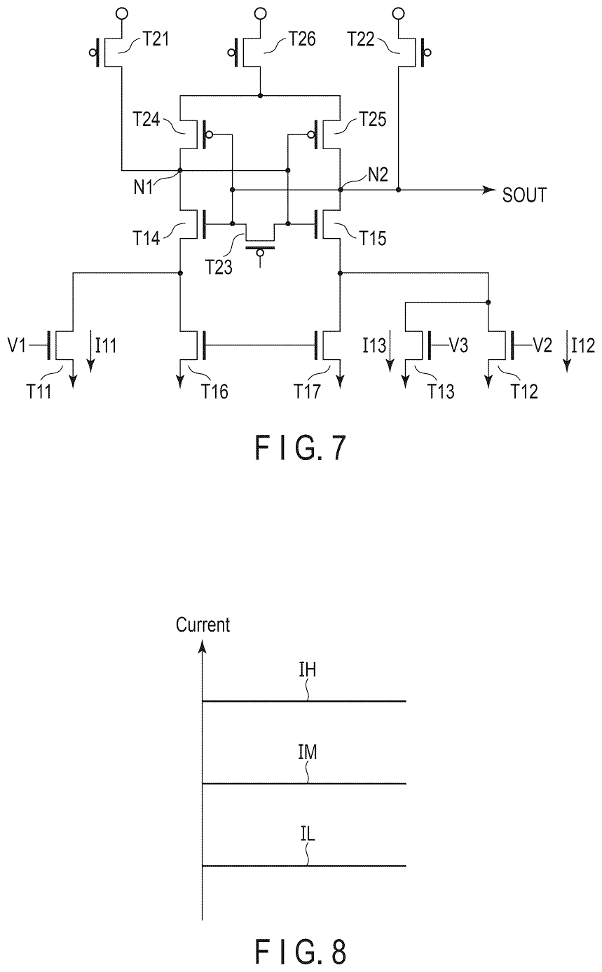

FIG. 7 is an electrical circuit diagram showing the configuration of the sense amplifier circuit 220.

The sense amplifier circuit 220 includes NMOS transistors T11 to T17 and PMOS transistors T21 to T26.

During the first half of the period SEN when the detection operation is carried out, the transistors T14 and T15, as well as the transistors T21, T22, and T23, are set to the on state, whereas the transistors T16 and T17, as well as the transistor T26, are set to the off state. Further, a voltage (first value) V1 is applied to the gate of the transistor T11 (the first transistor, first circuit portion), and a voltage (second value) V2 is applied to the gate of the transistor T12 (the second transistor, second circuit portion). Further, a voltage (third value) V3 is applied to the gate of the transistor T13 (the third transistor, third circuit portion) connected in parallel with the transistor T12.

Based on the states of the transistors described above, a current (first current) I11 depending on the voltage V1 flows through the transistor T11, a current (second current) I12 depending on the voltage V2 flows through the transistor T12, and a current (third current) I13 depending on the voltage V3 flows through the transistor T13.

During the second half of the period SEN, the transistors T21, T22, and T23 are set to the off state. The potential at a node N1, which is the connection point between the transistors T14 and T24, is determined by the current I11 immediately before the transistors T21, T22, and T23 are set to the off state. The potential at a node N2, which is the connection point between the transistors T15 and T25, is determined by a total current (I12+I13) of a current I12 and a current I13 at the time immediately before the transistors T21, T22, and T23 are set to the off state. Further, when the transistors T16 and T17 and the transistor T26 are set to the on state, the positive feedback of the circuit portion formed by the transistors T14, T15, T24, and T25 occurs, which increases the potential difference between the potential of the node N1 and that of the node N2. Thus, the potential of the node N1 and the potential of the node N2 are determined.

The potential (voltage) of the node N2, obtained as described above is output as a detection signal (H-level signal or L-level signal) corresponding to the target data from an output portion SOUT. In other words, based on the relationship between the magnitude of the current I11 and the magnitude of the total current (I12+I13) of the current I12 and current I13, the detection signal corresponding to the target data is output from the output portion SOUT.

Specifically, the output portion SOUT outputs a signal (either an H-level signal or an L-level signal) indicating that the target data is the same as the reference data when the magnitude of the current I11 is smaller than the magnitude of the total current (I12+I13), and when the magnitude of the current I11 is greater than the magnitude of the total current (I12+I13), it outputs a signal (the other of the H-level signal and the L-level signal) indicating that the target data is different from the reference data.

FIG. 8 is a diagram schematically showing the relationship of various currents flowing through the transistors T11, T12, and T13.

The current IL corresponds to the current I11 flowing through the transistor T11 when the magnetoresistance effect element 40 is in the low-resistance state, and the current IH corresponds to the current I11 flowing through the transistor T11 when the magnetoresistance effect element 40 is in the high-resistance state. The current IM is the current between the current IL and current IH, and corresponds to the total current (I12+I13) of the current I12 flowing through the transistor T12 and the current I13 flowing through the transistor T13 when the reference resistance state of the magnetoresistance effect element 40 is in the low-resistance state. In this case, the current I11 flowing through the transistor T11 (corresponding to the current IL) and the current I12 flowing through transistor T12 (corresponding to the current IL) when the target resistance state of the magnetoresistance effect element 40 is in the low-resistance state are substantially the same as each other. Therefore, the difference between current IM and the current IL, (IM IL) corresponds to the current I13 flowing through the transistor T13.

As can be seen from the above-provided description, in order to accurately detect the target data stored in the memory cell 30, it is necessary to accurately set the value of the current I13. For example, it is preferable to set the current I13 flowing through the transistor T13 so that the value of (IH−IM) and the value of (IM−IL) are approximately the same as each other.

Therefore, the voltage V3 applied to the transistor T13 is adjusted so that the current I13 flowing through the transistor T13 takes the appropriate value as described above. In the following description, the voltage V3 applied to the transistor T13 may as well be referred to as an offset voltage.

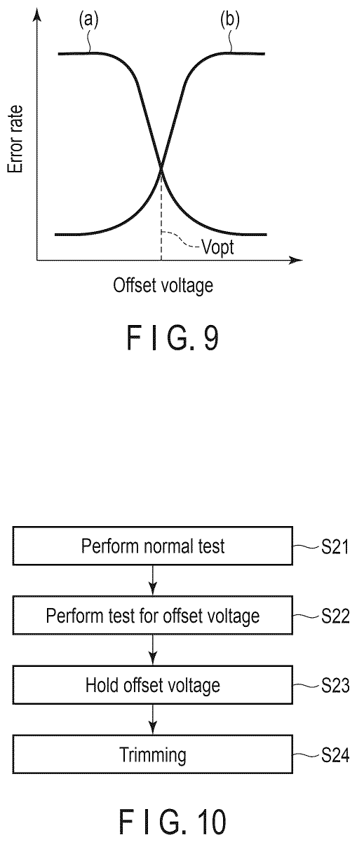

FIG. 9 is a diagram illustrating the method of determining the offset voltage (voltage V3) described above. The horizontal axis represents the offset voltage applied to the transistor T13, and the vertical axis represents the error rate when the target data is read from the memory cell.

A characteristic (a) represents the error rate when the magnetoresistance effect element 40 is set to a low-resistance state as the target resistance state, and a characteristic (b) represents the error rate when the magnetoresistance effect element 40 is set to a high-resistance state as the target resistance state. The reference resistance state of the magnetoresistance effect element 40 is the low resistance state.

As can be seen from the descriptions already provided, the total current (I12+I13) flowing through the transistors T12 and T13 increases as the offset voltage (voltage V3) increases. Further, in the case (a) where the magnetoresistance effect element 40 is set to the low-resistance state, the current I11 flowing through the transistor T11 is small. Therefore, when the magnetoresistance effect element 40 is set to the low-resistance state, the error rate decreases as the offset voltage increases. Conversely, in the case (b) where the magnetoresistance effect element 40 is set to the high-resistance state, the error rate decreases as the offset voltage decreases.

Therefore, in order to keep the error rate low in both cases where the magnetoresistance effect element 40 is set to the low-resistance state and where it is set to the high-resistance state, the offset voltage at the point of location where the characteristic (a) and characteristic (b) intersect each other becomes an ideal optimal offset voltage Vopt.

Ideally, the offset voltage described above should preferably be constant for all sense amplifier circuits 220 included in the memory circuit 200. In other words, the offset voltage should preferably be constant for all memory cell blocks 210 included in the memory circuit 200.

However, in practice, the offset voltage has a systematic distribution depending on the location of the memory cell block 210 due to process variations, and the like. Specifically, the resistance value of the magnetoresistance effect element 40 has a systematic distribution depending on the location of the memory cell block 210 and the like. Therefore, the value of the ideal optimal offset voltage is not constant. Therefore, when the offset voltages of all sense amplifier circuits 220 included in the memory circuit 200 are set to a constant value, the error rate may vary depending on the location of the memory cell blocks 210, which may result in creation of memory cell blocks 210 with high error rates.

In this embodiment, in order to suppress the error rate to low in each of the memory cell blocks 210, the offset voltage is adjusted for each of the sense amplifier circuits 220. That is, in this embodiment, the current I13 flowing through the transistor T13 is adjusted for each of the sense amplifier circuits 220.

The above-described operation is performed by the control circuit 300 and the like shown in FIG. 1. The configuration and operation of the control circuit 300 will now be described.

As shown in FIG. 1, the control circuit 300 includes an adjustment circuit 310 including a holding circuit 311 and a trimming circuit 312, and an operation control circuit 320. Further, a measurement circuit 400 is provided outside the control circuit 300. Note that, if possible, the measurement circuit 400 may be provided within the control circuit 300.

As can be seen from the description already provided, the adjustment circuit 310 adjusts the current I13 flowing through the transistor T13 for each of the sense amplifier circuits 220. Specifically, the adjustment circuit 310 adjusts the offset voltage (voltage V3) applied to the gate of the transistor T13 when the current I13 is allowed to flow through the transistor T13. In other words, the adjustment circuit 310 adjusts the current I13 (adjusts the offset voltage) so that the total current (I12+I13) becomes a current between the current I11 flowing through the transistor T11 when the magnetoresistance effect element 40 is in the low-resistance state and the current I11 flowing through the transistor T11 when the magnetoresistance effect element 40 is in the high-resistance state.

Now, with reference to the flowchart shown in FIG. 10, the operation of the memory device shown in FIG. 1 will be explained. Note that steps S21, S22, and S23 shown in FIG. 10 are basically performed before shipment, and a step S24 is basically performed after shipment (during actual operation after shipment).

First, a normal test is performed (S21). The normal test is a general test to be performed on the memory circuit 200 and the like.

Next, a test for an offset voltage is performed (S22). Specifically, a test is performed by the measurement circuit 400 to obtain the offset voltage described above for each of the memory cell blocks 210.

As already described, the offset voltage has a systematic distribution depending on the location of the memory cell block 210 and the like. Therefore, it is acceptable to consider that the memory cells 30 included in the same memory cell block 210 have substantially the same characteristics. For this reason, in this embodiment, the same offset voltage is set for the same memory cell block 210.

For example, the best offset voltage acquired for a single memory cell 30 (designated as a memory cell 30-1) is adopted as the offset voltage for the memory cell block 210 including the memory cell 30-1. Alternatively, the average value of a plurality of best offset voltages acquired for a plurality of memory cells 30 (designated as memory cells 30-1 to 30-n) may be adopted as the offset voltage for the memory cell block 210 including the memory cells 30-1 to 30-n. In this manner, offset voltages are acquired for each of the memory cell blocks 210 included in the memory cell circuit 200.

As described above, a plurality of offset voltages are obtained based on the results of the tests performed in advance for each of the memory cell blocks 210. The thus obtained offset voltages are held in the holding circuit 311 (S23). That is, the holding circuit 311 holds the offset voltages as adjustment control values for adjusting the current I13 of the transistor T13 for each of the sense amplifier circuits 220.

As described above, the pre-shipment operation is performed, and the offset voltages are held in the holding circuit 311 as adjustment control values.

After shipment, write operations and read operations and the like are actually performed on the memory cell circuit 200 by the user.

When a read operation is performed, data is read from the selected memory cell 30 based on the operating principle already described. In this embodiment, when a read operation is performed, the offset voltage (adjustment control value) held in the holding circuit 311 is trimmed by the trimming circuit 312 (S24).

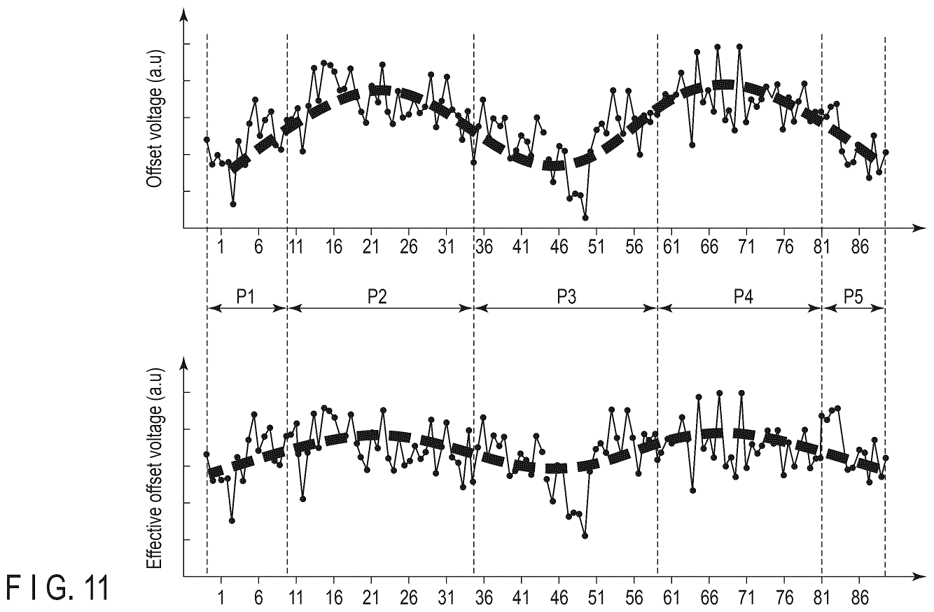

FIG. 11 is a diagram showing the trimming process performed by the trimming circuit 312. The upper section of FIG. 11 shows the distribution of offset voltages before the trimming process, and the lower section of FIG. 11 shows the distribution of offset voltages after the trimming process. The horizontal axis indicates the location of the memory cell block 210, and the vertical axis indicates the relationship between the offset voltage and the effective offset voltage. Each of the dots shown in the figure corresponds to the offset voltage obtained for the respective one of the memory cell blocks 210 by the processing steps of steps S21 to S23 described above.

As already described, the offset voltage usually varies systematically according to the location of the memory cell block 210. In the example shown in the upper section of FIG. 11, the offset voltage is relatively low in regions P1, P3, and P5, whereas the offset voltage is relatively high in regions P2 and P4.

Therefore, in this embodiment, in order to reduce the difference between offset voltages to some extent, the offset voltages of memory cell blocks 210 included in the regions P1, P3, and P5 are shifted overall so that the difference between the offset voltages of memory cell blocks 210 included in regions the P1, P3, and P5 and the offset voltages of memory cell blocks 210 included in the regions P2 and P4 becomes smaller. That is, by trimming the offset voltages held in the holding circuit 311 using the trimming circuit 312, the difference between the offset voltages is reduced to a certain extent.

As described above, the process of generating offset voltage (generation process of the offset voltages subjected to trimming process) is performed.

The operation control circuit 320 controls the first read operation, write operation, and second read operation already described above using the offset voltages subjected to the trimming process when reading out the target data stored in the selected memory cell 30.

As described above, in this embodiment, the adjustment circuit 310 is provided to adjust the current I13 flowing through the transistor T13 for each of the sense amplifier circuits 220. With this configuration, even if the adjustment control values (offset voltages in the embodiment described above) for obtaining the optimal current I13 are different among a plurality of memory cell blocks 210 (or among a plurality of sense amplifier circuits 220), it is possible to set appropriate adjustment control values for each of the memory cell blocks 210 (or for each of the sense amplifier circuits 220). Therefore, in this embodiment, it is possible to accurately read the target data stored in the memory cell 30.

Note that in the embodiment provided above, a magnetoresistance effect element is used as the variable resistance element, but it is also possible to use some other variable resistance element that exhibit one of a low-resistance state or a high-resistance state so as to be able to store different information corresponding to each of the resistance states.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A memory device comprising:
a memory circuit including a plurality of memory cell blocks each including a plurality of memory cells, and a plurality of sense amplifier circuits provided for the plurality of memory cell blocks, respectively; and
a control circuit controlling the memory circuit,
wherein
each of the plurality of memory cells includes a variable resistance element and a switching element connected in series with the variable resistance element, and stores data corresponding to one of a low-resistance state and a high-resistance state of the variable resistance element,
each of the plurality of sense amplifier circuits includes:
a first circuit portion through which a first current flows, the first current depending on a first value obtained by a first read operation that reads target data stored in a selected memory cell of the plurality of memory cells;
a second circuit portion through which a second current flows, the second current depending on a second value obtained by a second read operation that reads reference data written to the selected memory cell during a write operation performed after the first read operation;
a third circuit portion connected in parallel to the second circuit portion, through which a third current flows when the second current flows through the second circuit portion; and
an output portion which outputs a detection signal corresponding to the target data based on a relationship between a magnitude of the first current and a magnitude of a total current of the second current and the third current, and
the control circuit includes an adjustment circuit which adjusts the third current flowing through the third circuit portion with respect to each of the plurality of sense amplifier circuits.

2. The memory device of claim 1, wherein
the first, second, and third circuit portions include first, second, and third transistors, respectively.

3. The memory device of claim 2, wherein
the adjustment circuit adjusts a voltage applied to a gate of the third transistor when the third current flows through the third circuit portion.

4. The memory device of claim 1, wherein
the adjustment circuit adjusts the third current so that the magnitude of the total current is between the magnitude of the first current when the variable resistance element is in the low-resistance state and the magnitude of the first current when the variable resistance element is in the high-resistance state.

5. The memory device of claim 1, wherein
the adjustment circuit includes a holding circuit which holds an adjustment control value adjusting the third current with respect to each of the plurality of sense amplifier circuits.

6. The memory device of claim 5, wherein
the adjustment control value is held in the holding circuit based on a result of a test performed in advance for the plurality of memory cell blocks.

7. The memory device of claim 5, wherein
the adjustment circuit further includes a trimming circuit which trims the adjustment control value held in the holding circuit.

8. The memory device of claim 1, wherein
the control circuit further includes an operation control circuit which controls the first read operation, the write operation, and the second read operation.

9. The memory device of claim 1, wherein
the output portion outputs a signal indicating that the target data is same as the reference data as the detection signal when the magnitude of the first current is smaller than the magnitude of the total current, and outputs a signal indicating that the target data is different from the reference data as the detection signal when the magnitude of the first current is greater than the magnitude of the total current.

10. The memory device of claim 1, wherein
the variable resistance element and the switching element are stacked in a direction perpendicular to a plane in which the plurality of memory cells are arranged.

11. The memory device of claim 1, wherein
the variable resistance element is a magnetoresistance effect element.

12. The memory device of claim 1, wherein
the switching element is a two-terminal switching element having a characteristic of changing from an off state to an on state when a voltage applied between two terminals thereof reaches or exceeds a threshold voltage.

13. The memory device of claim 1, wherein
the variable resistance element has a characteristic of storing different information corresponding to a resistance state thereof.
